(19) United States
(12) Patent Application Publication
(10) Pub. No.: US 2026/0032920 A1
(43) Pub. Date: Jan. 29, 2026

(54) MAGNETORESISTIVE MEMORY DEVICE AND METHOD OF MANUFACTURING THE SAME

(71) Applicant: Samsung Electronics Co., Ltd., Suwon-si (KR)

(72) Inventors: Jonghyuk LEE, Suwon-si (KR); Youngkeol KIM, Suwon-si (KR); Junho PARK, Suwon-si (KR); Sunghyuk SONG, Suwon-si (KR); Manjin EOM, Suwon-si (KR)

(73) Assignee: Samsung Electronics Co., Ltd., Suwon-si (KR)

(21) Appl. No.: 19/207,735

(22) Filed: May 14, 2025

(30) Foreign Application Priority Data
Jul. 23, 2024 (KR) 10-2024-0097512

(51) Int. Cl. H10B 61/00; H10N 50/01; H10N 50/10

(52) U.S. Cl. CPC H10B 61/10; H10N 50/01; H10N 50/10

(57) ABSTRACT

A method of manufacturing a magnetoresistive memory device includes forming an isolation layer and a via contact on a substrate, the via contact having a sidewall surrounded by the isolation layer, forming a memory stack on the isolation layer and the via contact, the memory stack comprising a lower electrode layer, a magnetic tunnel junction layer, and an upper electrode layer, forming a plurality of memory cells by patterning the memory stack, forming a metal material redeposited layer during the ion beam etching process on an upper surface of the isolation layer, and forming an insulating liner on the plurality of memory cells. The insulating liner comprises a first portion covering the plurality of memory cells, the first portion comprising a first oxide, and a second portion formed by oxidation of at least a portion of the metal material redeposited layer, the second portion comprising a second oxide.

### CROSS-REFERENCE TO RELATED APPLICATION

This application is based on and claims priority under 35 U.S.C. § 119 to Korean Patent Application No. 10-2024-0097512, filed on Jul. 23, 2024, in the Korean Intellectual Property Office, the disclosure of which is incorporated by reference herein in its entirety.

### BACKGROUND

Some example embodiments of the inventive concepts relate to a magnetoresistive memory device and a method of manufacturing the magnetoresistive memory device, and more particularly, to a magnetoresistive random-access memory device including a magnetic tunnel junction, and a method of manufacturing the magnetoresistive random-access memory device.

Research has been conducted on electronic devices using magnetoresistive characteristics of magnetic tunnel junction (MTJ) structures. In particular, a magnetoresistive memory device including an MTJ stack includes a thin tunneling insulating layer arranged between two magnetic material layers. Data may be stored by using the magnetoresistance of an MTJ, and such magnetoresistive memory devices have been proposed as devices that enable efficient and fast in-memory computing or neuromorphic computing.

### SUMMARY

Some example embodiments of the inventive concepts provide a magnetoresistive memory device with improved device performance and a method of manufacturing the magnetoresistive memory device.

According to some example embodiments of the inventive concepts, there is provided a method of manufacturing a magnetoresistive memory device, the method including forming an isolation layer and a via contact on a substrate, the via contact having a sidewall surrounded by the isolation layer, forming a memory stack on the isolation layer and the via contact, the memory stack comprising a lower electrode layer, a magnetic tunnel junction layer, and an upper electrode layer, forming a plurality of memory cells by patterning the memory stack using an ion beam etching process, forming a metal material redeposited layer during the ion beam etching process on an upper surface of the isolation layer, and forming an insulating liner on the plurality of memory cells by using an atomic layer deposition process. The insulating liner comprises a first portion covering the plurality of memory cells, the first portion comprising a first oxide, and a second portion formed by oxidation of at least a portion of the metal material redeposited layer, the second portion comprising a second oxide.

According to some example embodiments of the inventive concepts, there is provided a method of manufacturing a magnetoresistive memory device, the method including forming a wiring line structure on a substrate, the wiring line structure comprising a wiring line layer and an insulating layer, forming an isolation layer on the wiring line structure, forming a memory stack on the isolation layer, the memory stack comprising a lower electrode layer, a magnetic tunnel junction layer, and an upper electrode layer, forming a plurality of memory cells by removing a portion of the memory stack using an ion beam etching process, removing a portion of an upper side of the isolation layer during the ion beam etching process so that the isolation layer has a recessed upper surface, and a metal material redeposited layer is formed on the recessed upper surface of the isolation layer, forming a first capping spacer on sidewalls of the plurality of memory cells, and oxidizing a portion of the metal material redeposited layer that is not covered by the first capping spacer.

According to some example embodiments of the inventive concepts, there is provided a method of manufacturing a magnetoresistive memory device, the method including forming a wiring line structure on a substrate, the wiring line structure comprising a wiring line layer and an insulating layer, forming an isolation layer on the wiring line structure, forming a memory stack on the isolation layer, the memory stack comprising a lower electrode layer, a magnetic tunnel junction layer, and an upper electrode layer, forming a plurality of memory cells by removing a portion of the memory stack by using an ion beam etching process, removing a portion of an upper side of the isolation layer during the ion beam etching process so that the isolation layer has a recessed upper surface, and a metal material redeposited layer is formed on the recessed upper surface of the isolation layer, forming a first capping spacer on sidewalls of the plurality of memory cells, such that a first portion of the metal material redeposited layer is covered by the first capping spacer, and a second portion of the metal material redeposited layer is not covered by the first capping spacer, and forming an insulating liner by an atomic layer deposition process using oxygen radicals. A first portion of the insulating liner covers the plurality of memory cells and the first capping spacer, and a second portion of the insulating liner is formed by oxidizing the second portion of the metal material redeposited layer.

### BRIEF DESCRIPTION OF THE DRAWINGS

Embodiments of the inventive concepts will be more clearly understood from the following detailed description taken in conjunction with the accompanying drawings in which:

FIG. 1 is a circuit diagram illustrating a magnetoresistive memory device according to some example embodiments;

FIG. 2 is a layout diagram illustrating a magnetoresistive memory device according to some example embodiments;

FIG. 3 is a cross-sectional view of the magnetoresistive memory of FIG. 2, taken along a line A-A′ of FIG. 2;

FIG. 4 is an enlarged view of a region CX1 of FIG. 3;

FIG. 5 is a cross-sectional view illustrating a magnetoresistive memory device according to some example embodiments;

FIG. 6 is an enlarged view of a region CX1 of FIG. 5;

FIG. 7 is a cross-sectional view illustrating a magnetoresistive memory device according to some example embodiments;

FIG. 8 is a cross-sectional view illustrating a magnetoresistive memory device according to some example embodiments;

FIGS. 9, 10, 11, 12, 13, 14, 15A, 15B, 16A, 16B, 17A, 17B, 18, and 19 are cross-sectional views illustrating a method of manufacturing a magnetoresistive memory device according to some example embodiments;

FIGS. 20A, 20B, 21A, and 21B are cross-sectional views illustrating a method of manufacturing a magnetoresistive memory device according to some example embodiments; and

FIGS. 22A, 22B, 23A, and 23B are cross-sectional views illustrating a method of manufacturing a magnetoresistive memory device according to some example embodiments.

### DETAILED DESCRIPTION

Some example embodiments of the inventive concepts will now be described more fully with reference to the accompanying drawings, in which example embodiments of the inventive concepts are shown.

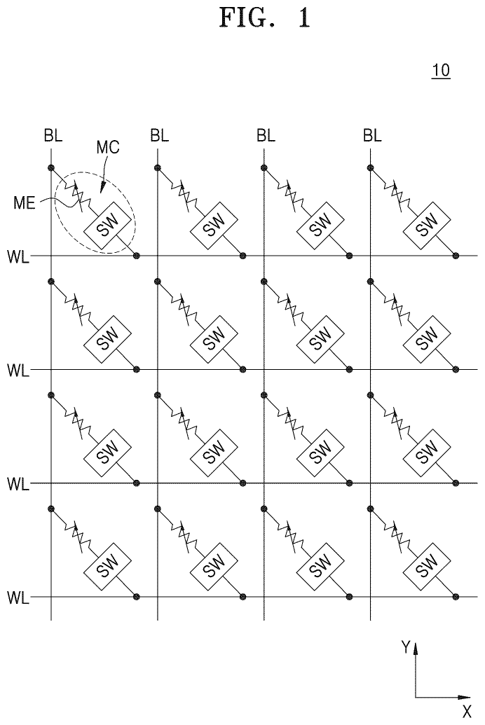

FIG. 1 is a circuit diagram illustrating a magnetoresistive memory device 10 according to some example embodiments.

Referring to FIG. 1, the magnetoresistive memory device 10 may include a plurality of word lines WL each extending in a first horizontal direction X, a plurality of bit lines BL each extending in a second horizontal direction Y, and a plurality of memory cells MC arranged between the plurality of word lines WL and the plurality of bit lines BL and connected to the plurality of word lines WL and the plurality of bit lines BL.

Each of the plurality of memory cells MC may include a memory unit ME for storing information and a switching unit SW configured to select a memory cell. In some example embodiments, the switching unit SW may include an accessor device, such as a transistor, a diode, and an ovonic threshold switching (OTS) device. For example, as the switching unit SW of a selected memory cell MC is turned on through the plurality of word lines WL and the plurality of bit lines BL, a voltage is applied to the memory unit ME of the memory cell MC, and a current may flow to the memory cell MC. For example, the memory unit ME may include a magnetic tunnel junction of which resistance varies according to a voltage value applied to the memory unit ME. For example, the resistance of the memory unit ME may reversibly transition between a first state and a second state according to a voltage applied to the memory unit ME of the selected memory cell MC.

Depending on a change in resistance of the memory unit ME, digital information, such as “0” or “1”, may be stored in the memory cell MC, and the digital information may be erased from the memory cell MC. For example, data may be written in the memory cell MC as a high-resistance state “0” or a low-resistance state “1.” However, the memory cell MC according to some example embodiments is not limited to the digital information of the high-resistance state “0” and the low-resistance state “1” as described above, and may store various resistance states.

A memory cell MC may be addressed by selecting a word line WL and a bit line BL, the memory cell MC may be programmed by applying a certain signal between the word line WL and the bit line BL, and a current value may be measured through the bit line BL, and thus information according to a resistance value of the memory unit ME configuring the memory cell MC may be read.

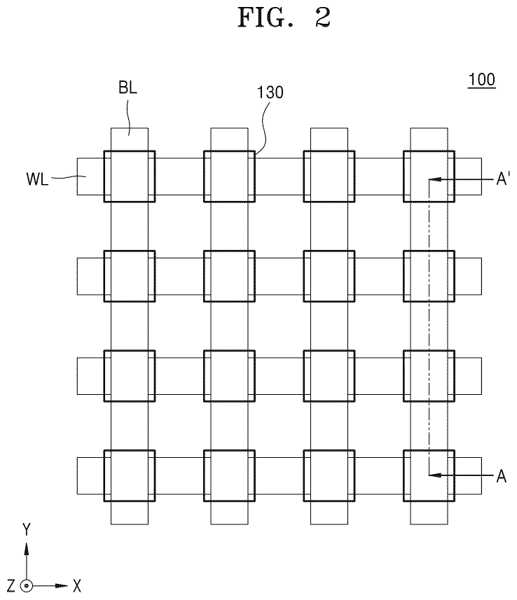

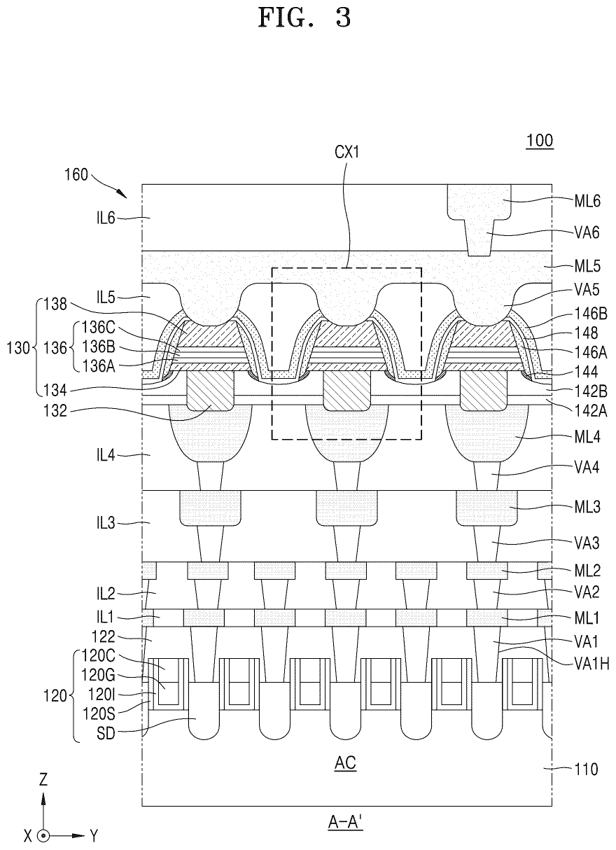

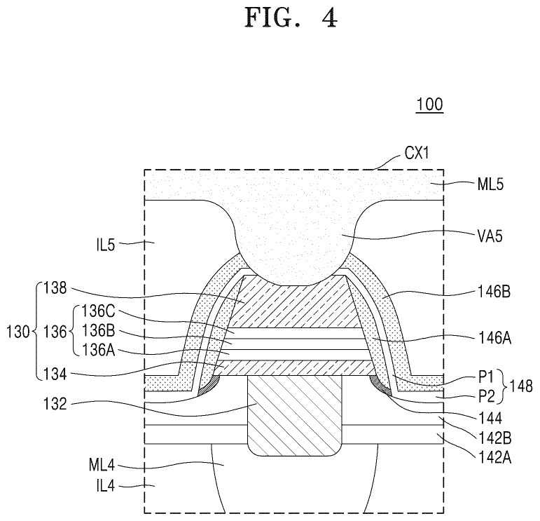

FIG. 2 is a layout diagram illustrating a magnetoresistive memory device 100 according to some example embodiments. FIG. 3 is a cross-sectional view of the magnetoresistive memory device 100 of FIG. 2, taken along a line A-A′ of FIG. 2, and FIG. 4 is an enlarged view of a region CX1 of FIG. 3.

Referring to FIGS. 2 to 4, a transistor 120 may be arranged on a substrate 110, and a magnetoresistive memory cell 130 electrically connected to the transistor 120 may be arranged. A back-end-of-line (BEOL) structure 160 electrically connected to the transistor 120 may be arranged above the substrate 110, and the magnetoresistive memory cell 130 may be arranged within the BEOL structure 160 to be covered with the BEOL structure 160.

In some example embodiments, the transistor 120 may include various types of transistors, such as a flat-panel transistor, a FinFET transistor, a multi-bridge-channel transistor, a gate-all-around-type transistor, a ferroelectric transistor, and a negative-charge transistor. The transistor 120 may correspond to the switching unit SW (refer to FIG. 1) as described with reference to FIG. 1.

FIG. 3 illustrates a case in which the transistor 120 is a FinFET transistor as an example. For example, the transistor 120 may include a gate insulating layer 120I, a gate electrode 120G, and a gate capping layer 120C, which are sequentially arranged on an upper surface of an active region AC (e.g., a portion of the substrate 110, which protrudes on an upper side of the substrate 110 in a fin shape) defined in the substrate 110. In addition, the transistor 120 may include a gate spacer 120S arranged on each of sidewalls of the gate insulating layer 1201, the gate electrode 120G, and the gate capping layer 120C, and a source/drain region SD arranged on both sides of the gate spacer 120S and within the substrate 110.

In some example embodiments, a switching device, such as a diode, an ovonic threshold switching device, and a unipolar switching device, may also be arranged on the substrate 110 instead of the transistor 120.

A first interlayer insulating film 122 covering the transistor 120 may be arranged above the substrate 110. The first interlayer insulating film 122 may be formed with a sufficiently large thickness to completely cover an upper surface of the transistor 120. In some example embodiments, the first interlayer insulating film 122 may include silicon oxide or SiOC. However, example embodiments are not limited thereto.

The BEOL structure 160 may be arranged on the first interlayer insulating film 122. The BEOL structure 160 may include first to sixth insulating layers IL1, IL2, IL3, IL4, IL5, and IL6, first to sixth wiring line layers ML1, ML2, ML3, ML4, ML5, and ML6, and first to sixth vias VA1, VA2, VA3, VA4, VA5, and VA6. The BEOL structure 160 may correspond to an electrical connection structure that connects at least one of the substrate 110, the transistor 120, and/or the magnetoresistive memory cell 130 and may also be referred to as a line structure. FIG. 3 illustrates an example in which the BEOL structure 160 includes six wiring line layers arranged at different vertical levels, but the number of wiring line layers may vary from that illustrated in FIG. 3, and for example, the BEOL structure 160 may also include three, four, five, seven or more wiring line layers.

In some example embodiments, the first via VA1 may be arranged within a via hole VA1H that penetrates the first interlayer insulating film 122. The first via VA1 may be electrically connected to the source/drain region SD of the transistor 120 and the gate electrode 120G of the transistor 120. For example, the first via VA1 may include a metal material that completely fills the via hole VA1H, for example, tungsten (W).

The first wiring line layer ML1 and the first insulating layer IL1 may be formed on the first interlayer insulating film 122. The first wiring line layer ML1 may be electrically connected to the first via VA1, and the first insulating layer IL1 may be arranged to cover a sidewall of the first wiring line layer ML1.

The second wiring line layer ML2 may be arranged at a higher vertical level than the first wiring line layer ML1, and the second via VA2 may be arranged between the second wiring line layer ML2 and the first wiring line layer ML1. The second insulating layer IL2 may be arranged to cover sidewalls of the second wiring line layer ML2 and the second via VA2. The third wiring line layer ML3 may be arranged at a higher vertical level than the second wiring line layer ML2, and the third via VA3 may be arranged between the third wiring line layer ML3 and the second wiring line layer ML2. The third insulating layer IL3 may be arranged to cover sidewalls of the third wiring line layer ML3 and the third via VA3. The fourth wiring line layer ML4 may be arranged at a higher vertical level than the third wiring line layer ML3, and the fourth via VA4 may be arranged between the fourth wiring line layer ML4 and the third wiring line layer ML3. The fourth insulating layer IL4 may be arranged to cover sidewalls of the fourth wiring line layer ML4 and the fourth via VA4.

The magnetoresistive memory cell 130 (or a magnetoresistive memory unit) may be arranged on the fourth wiring line layer ML4. The magnetoresistive memory cell 130 may include a via contact 132, a lower electrode 134, a magnetic tunnel junction pattern 136, and an upper electrode 138. The magnetoresistive memory cell 130 may correspond to the memory unit ME (refer to FIG. 1) as described with reference to FIG. 1.

A first isolation layer 142A and a second isolation layer 142B may be sequentially arranged on the fourth insulating layer IL4. The first isolation layer 142A may include at least one of silicon oxide, silicon oxynitride, silicon carbon oxide, silicon nitride, and silicon carbon nitride. However, example embodiments are not limited thereto. The second isolation layer 142B may include at least one of silicon oxide, silicon oxynitride, silicon carbon oxide, silicon nitride, and silicon carbon nitride. However, example embodiments are not limited thereto.

The via contact 132 may be arranged to penetrate the first isolation layer 142A and the second isolation layer 142B. A bottom surface of the via contact 132 may be in contact with an upper surface of the fourth wiring line layer ML4. The via contact 132 may include W, cobalt (Co), ruthenium (Ru), molybdenum (Mo), titanium nitride (TiN), tungsten nitride (WN), cobalt nitride (CoN), molybdenum nitride (MoN), or a combination thereof. However, example embodiments are not limited thereto.

The lower electrode 134, the magnetic tunnel junction pattern 136, and the upper electrode 138 may be sequentially arranged on the via contact 132 and the second isolation layer 142B. A stacked structure of the lower electrode 134, the magnetic tunnel junction pattern 136, and the upper electrode 138 may have inclined sidewalls, and for example, a horizontal width of the lower electrode 134 may be greater than a horizontal width of the upper electrode 138.

In some example embodiments, each of the lower electrode 134 and the upper electrode 138 may include W, Co, Ru, Mo, TiN, WN, CoN, MoN, or a combination thereof. However, example embodiments are not limited thereto.

The magnetic tunnel junction pattern 136 may include a fixed layer 136A, a tunnel barrier 136B, and a free layer 136C.

In some example embodiments, the fixed layer 136A may include Fe, Co, Ni, or alloys thereof and may include a multi-layered structure thereof. For example, the fixed layer 136A may include CoFeB, CoFe, NiFe, FePt, CoPt, or the like. However, example embodiments are not limited thereto.

In some example embodiments, the tunnel barrier 136B may include at least one selected from among oxides of magnesium (Mg), titanium (Ti), aluminum (Al), magnesium-zinc (MgZn), and magnesium-boron (MgB), and nitrides of Ti and vanadium (V). For example, the tunnel barrier 136B may be a magnesium oxide (MgO) film. Alternatively, the tunnel barrier 136B may include a plurality of layers. For example, the tunnel barrier 136B may include Mg/MgO, MgO/Mg, or Mg/MgO/Mg. However, example embodiments are not limited thereto.

In some example embodiments, the free layer 136C may include Fe, Co, Ni, or alloys thereof and may include a multi-layered structure thereof. The free layer 136C may include a Co-M1 alloy (where M1 is at least one metal selected from among Pt, Pd, and Ni) or a Fe-M2 alloy (where M2 is at least one metal selected from among Pt, Pd, and Ni). In some example embodiments, the free layer 136C may further include at least one material selected from among B, C, Cu, Ag, Au, Ru, Ta, and Cr. In some example embodiments, the free layer 136C may be formed to include a multi-layered structure of (Co/Pt) m, (Co/Pd) m, or (Co/Ni) m (where m is a natural number). However, example embodiments are not limited thereto.

A metal material residue layer 144 may be arranged on the second isolation layer 142B around the lower electrode 134. The metal material residue layer 144 may include at least one of Fe, Co, Ni, Ru, Ti, Pd, Pt, and Mo. However, example embodiments are not limited thereto. The metal material residue layer 144 may be formed by particles of metal materials contained in the lower electrode 134, the magnetic tunnel junction pattern 136, and the upper electrode 138, which are absorbed onto the second isolation layer 142B, in a process of etching the lower electrode 134, the magnetic tunnel junction pattern 136, and the upper electrode 138 by using a relatively high energy ion beam.

A first capping spacer 146A, an insulating liner 148, and a second capping spacer 146B may be sequentially arranged on a sidewall of the stacked structure including the lower electrode 134, the magnetic tunnel junction pattern 136, and the upper electrode 138.

The first capping spacer 146A may be arranged on a sidewall of the lower electrode 134, a sidewall of the magnetic tunnel junction pattern 136, and a sidewall of the upper electrode 138, and a lower side of the first capping spacer 146A may cover the metal material residue layer 144. An end portion of the lower side of the first capping spacer 146A may be arranged to overlap the metal material residue layer 144. The first capping spacer 146A may include silicon nitride or silicon oxynitride. However, example embodiments are not limited thereto. For example, a plurality of first capping spacers 146A may be arranged on a sidewall of each of a plurality of magnetoresistive memory cells 130.

The insulating liner 148 may be arranged on the first capping spacer 146A and extend onto the upper surface of the second isolation layer 142B. The insulating liner 148 may include a first portion P1 arranged on a sidewall of the first capping spacer 146A and a second portion P2 arranged on the upper surface of the second isolation layer 142B. The second portion P2 of the insulating liner 148 may be continuously connected to the first portion P1.

In some example embodiments, the first portion P1 of the insulating liner 148 may include a different material from a material included in the second portion P2. In some example embodiments, the first portion P1 of the insulating liner 148 may include a first oxide, and the second portion P2 of the insulating liner 148 may include a second oxide. In some example embodiments, the first oxide may include at least one of silicon oxide, titanium oxide, and aluminum oxide. However, example embodiments are not limited thereto. In some example embodiments, the second oxide may be an oxide including a metal. For example, the second oxide may include at least one of silicon metal oxide, titanium metal oxide, and aluminum metal oxide, and the metal included in the second oxide may be at least one of Fe, Co, Ni, Ru, Ti, Pd, Pt, and Mo. However, example embodiments are not limited thereto.

In some example embodiments, the first portion P1 of the insulating liner 148 may include the first oxide represented by a chemical formula of AOₓ, and A may include at least one of Si, Ti, and Al. However, example embodiments are not limited thereto. In some example embodiments, the second portion P2 of the insulating liner 148 may include the second oxide represented by a chemical formula of AMₓO_{y}, A may include at least one of Si, Ti, and Al, and M may include at least one of Fe, Co, Ni, Ru, Ti, Pd, Pt, and Mo. However, example embodiments are not limited thereto.

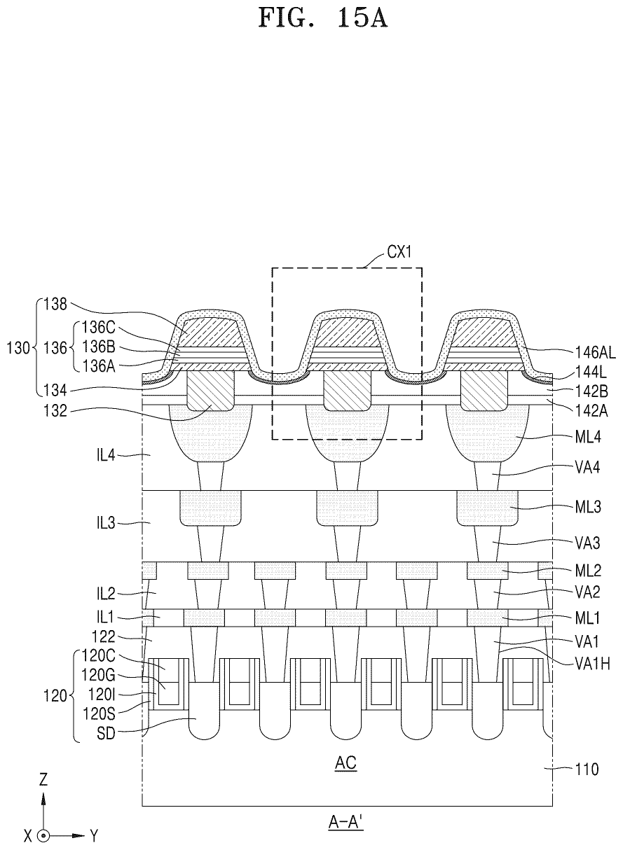

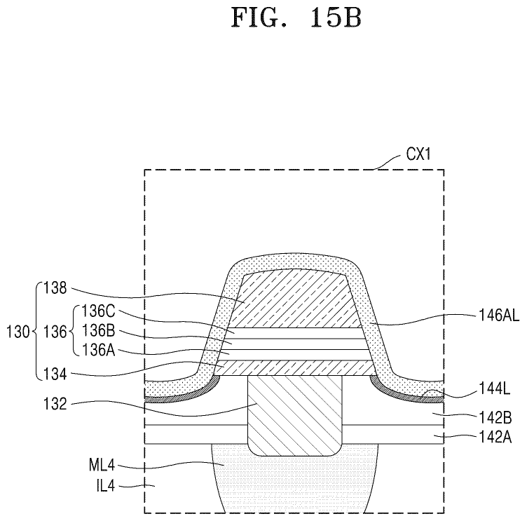

In some example embodiments, the first portion P1 of the insulating liner 148 may include the first oxide formed by an atomic layer deposition process, and the second portion P2 of the insulating liner 148 may include the second oxide formed by oxidation of a portion of a metal material redeposited layer 144L (refer to FIGS. 15A and 15B) formed on the second isolation layer 142B through an atomic layer deposition process. In some example embodiments, the first portion P1 of the insulating liner 148 may include silicon oxide formed by an atomic layer deposition process, and the second portion P2 of the insulating liner 148 may include silicon metal oxide formed by oxidation of a portion of the metal material redeposited layer 144L formed on the second isolation layer 142B through an atomic layer deposition process. In some example embodiments, the first portion P1 of the insulating liner 148 may include titanium oxide formed by an atomic layer deposition process, and the second portion P2 of the insulating liner 148 may include titanium metal oxide formed by oxidation of a portion of the metal material redeposited layer 144L formed on the second isolation layer 142B through an atomic layer deposition process. In some example embodiments, the first portion P1 of the insulating liner 148 may include aluminum oxide formed by an atomic layer deposition process, and the second portion P2 of the insulating liner 148 may include aluminum metal oxide formed by oxidation of a portion of the metal material redeposited layer 144L formed on the second isolation layer 142B through an atomic layer deposition process.

In some example embodiments, the type of a metal element included in the second portion P2 may vary depending on a type of a metal element included in the magnetic tunnel junction pattern 136 of the magnetoresistive memory cell 130. As the second portion P2 is formed by oxidation of a portion of the metal material redeposited layer 144L, the metal material residue layer 144 may not be arranged between the second portion P2 and the second isolation layer 142B arranged below the second portion P2.

The second portion P2 of the insulating liner 148 may be arranged between two adjacent magnetoresistive memory cells 130, and accordingly, the metal material residue layer 144 around one magnetoresistive memory cell 130 may not be electrically connected to the metal material residue layer 144 around another magnetoresistive memory cell 130 adjacent to the one magnetoresistive memory cell 130. For example, the second portion P2 of the insulating liner 148 may be arranged between the metal material residue layer 144 around the one magnetoresistive memory cell 130 and the metal material residue layer 144 around the other one magnetoresistive memory cell 130 adjacent to the one magnetoresistive memory cell 130.

In some example embodiments, the second isolation layer 142B may have a recessed upper surface shape, and a bottom surface of the metal material residue layer 144 on the recessed upper surface of the second isolation layer 142B may be continuously connected to a bottom surface of the second portion P2 of the insulating liner 148.

The second capping spacer 146B may be arranged on the insulating liner 148. The second capping spacer 146B may be conformally arranged on the first portion P1 and the second portion P2 of the insulating liner 148. The second capping spacer 146B may include silicon nitride or silicon oxynitride. However, example embodiments are not limited thereto.

The fifth insulating layer IL5 may be formed on the second capping spacer 146B. The fifth wiring line layer ML5 may be arranged on the fifth insulating layer IL5, and the fifth via VA5 may be arranged between the fifth wiring line layer ML5 and the upper electrode 138. FIG. 3 illustrates a case in which the fifth wiring line layer ML5 and the fifth via VA5 are integrally formed so that a clear boundary line between the fifth wiring line layer ML5 and the fifth via VA5 is not identified as an example, but in other embodiments, the fifth wiring line layer ML5 and the fifth via VA5 may not be integrally formed, and a boundary line between the fifth wiring line layer ML5 and the fifth via VA5 may also be identified.

The sixth wiring line layer ML6 may be arranged at a higher vertical level than the fifth wiring line layer ML5, and the sixth via VA6 may be arranged between the sixth wiring line layer ML6 and the fifth wiring line layer ML5. The sixth insulating layer IL6 may be arranged to cover sidewalls of the sixth wiring line layer ML6 and the sixth via VA6.

FIG. 3 illustrates a case in which the magnetoresistive memory cell 130 is arranged between the fourth wiring line layer ML4 and the fifth wiring line layer ML5 as an example, but in other embodiments, the position of the magnetoresistive memory cell 130 may vary. For example, the magnetoresistive memory cell 130 may also be arranged between the third wiring line layer ML3 and the fourth wiring line layer ML4, or the magnetoresistive memory cell 130 may also be arranged between the fifth wiring line layer ML5 and the sixth wiring line layer ML6.

In some example embodiments, one magnetoresistive memory cell 130 may be electrically connected to the transistor 120 connected to the one magnetoresistive memory cell 130 through wiring line layers and vias of the BEOL structure 160. For example, the gate electrode 120G of the transistor 120 or the first wiring line layer ML1 or the second wiring line layer ML2 electrically connected to the gate electrode 120G may function as the word line WL (refer to FIG. 1). The fifth wiring line layer ML5 arranged on the magnetoresistive memory cell 130 may function as the bit line BL of FIG. 1.

In some example embodiments, in a data write operation, the transistor 120 may be turned on by a voltage applied to a selected word line WL, a resistance of the magnetoresistive memory cell 130 electrically connected to the source/drain region SD of the transistor 120 may be changed by a write voltage applied to a selected bit line BL (for example, the resistance may transition from a high-resistance state to a low-resistance state, or vice versa, from a low-resistance state to a high-resistance state), and data may be stored in the magnetoresistive memory cell 130. In addition, in a data read operation, as a current value output from the magnetoresistive memory cell 130 is sensed by a read voltage applied to the selected bit line BL, data stored in the magnetoresistive memory cell 130 may be read.

Although not illustrated in the drawings, a plurality of peripheral circuit transistors forming a driving circuit for driving a plurality of memory cells may be formed on the substrate 110. For example, the driving circuit may be peripheral circuits capable of processing data input/output to/from the plurality of memory cells. For example, the peripheral circuits may be page buffers, latch circuits, cache circuits, column decoders, sense amplifiers, data in/out circuits, or row decoders.

In general, memory cells included in a magnetoresistive memory layer may be formed within a BEOL structure and may, for example, be positioned between an Mx line and an Mx+1 line. However, a metal material is attached or redeposited on an insulating layer or a device isolation layer in a process of sequentially patterning an upper electrode, a magnetic tunnel junction pattern, and a lower electrode, causing leakage current between adjacent memory cells. Although a method of performing a recess process to remove a redeposited layer of the metal material has been proposed, local erosion of the insulating layer or the device isolation layer may occur in the recess process, and in this case, process defects may occur, such as a wiring line layer arranged below the insulating layer or the device isolation layer being exposed or damaged in the recess process, thereby reducing the reliability of memory cells.

According to the embodiments described above, the insulating liner 148 may be formed by using an atomic layer deposition process instead of performing a recess process to remove a metal material redeposited layer. In a process of forming the insulating liner 148, the metal material redeposited layer may be oxidized and converted into a second oxide including a metal, and the second portion P2 of the insulating liner 148 may be formed. Accordingly, even at fine pitches, leakage current between adjacent memory cells may be significantly reduced. In addition, the recess process to remove the metal material redeposited layer may be omitted, and thus undesired exposure or damage to an underlying line material may be reduced and/or prevented. Accordingly, the magnetoresistive memory device 100 may have improved device performance.

For example, in the case of a magnetoresistive memory device according to Comparative Example 1 in which the insulating liner 148 is not formed, a current leakage path between adjacent memory cells may be generated by a metal material redeposited layer when a distance between the adjacent memory cells is relatively small, and a relatively high leakage current of approximately 1×10⁻³ A occurred. In the case of a magnetoresistive memory device according to Comparative Example 2 in which a recess process is performed, a leakage current of 1×10⁻⁶ A occurred, which was significantly improved compared to Comparative Example 1, but a high level of leakage current still occurred. In contrast, in the case of the magnetoresistive memory device according to the embodiments in which the insulating liner 148 is formed by using an atomic layer deposition process, a significantly reduced leakage current of approximately 1×10⁻¹⁰ A or 1×10⁻¹¹ A occurred.

Accordingly, the magnetoresistive memory device 100 according to some example embodiments may have significantly reduced leakage current between adjacent memory cells even at fine pitches, thereby having improved device performance.

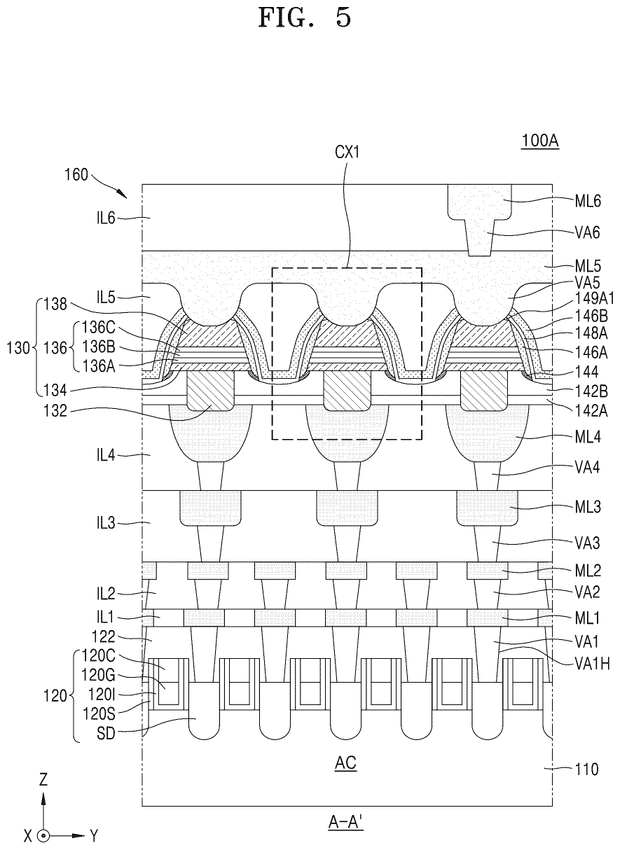

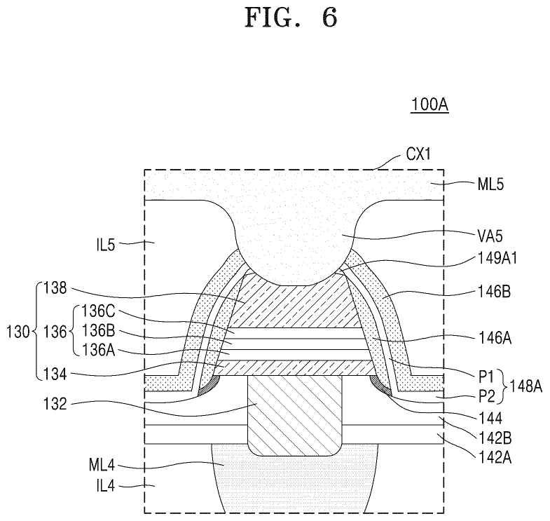

FIG. 5 is a cross-sectional view of a magnetoresistive memory device 100A according to some example embodiments. FIG. 6 is an enlarged view of a region CX1 of FIG. 5.

Referring to FIGS. 5 and 6, a first oxide layer 149A1 may be arranged on an upper surface of the upper electrode 138, and a first portion P1 of an insulating liner 148A may be arranged on the first oxide layer 149A1. In some example embodiments, the first oxide layer 149A1 may include a metal oxide of a material included in the upper electrode 138. For example, when the upper electrode 138 includes titanium, the first oxide layer 149A1 may include titanium oxide. For example, when the upper electrode 138 includes titanium nitride, the first oxide layer 149A1 may include titanium oxynitride. However, example embodiments are not limited thereto. A second portion P2 of the insulating liner 148A may be arranged on the second isolation layer 142B.

In some example embodiments, an ashing process may be performed at a relatively high temperature before performing an atomic layer deposition process to form the insulating liner 148A, and a portion of an upper side of the upper electrode 138 may be oxidized to form the first oxide layer 149A1 in the ashing process. Accordingly, the first oxide layer 149A1 may be arranged between the insulating liner 148A and the upper surface of the upper electrode 138.

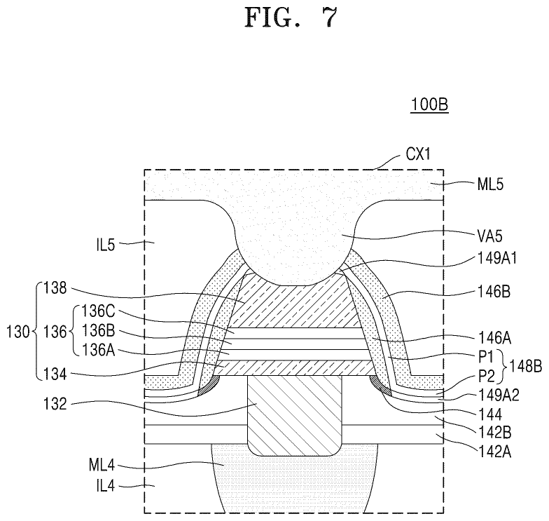

FIG. 7 is a cross-sectional view of a magnetoresistive memory device 100B according to some example embodiments.

Referring to FIG. 7, a second oxide layer 149A2 may be arranged on the upper surface of the second isolation layer 142B, and a second portion P2 of an insulating liner 148B may be arranged on the second oxide layer 149A2. In some example embodiments, the second oxide layer 149A2 may include a metal oxide represented by a chemical formula of MₓO_{y}, and M may include at least one of Fe, Co, Ni, Ru, Ti, Pd, Pt, and Mo. However, example embodiments are not limited thereto.

A first portion P1 of the insulating liner 148B may include a first oxide, and the first oxide may include at least one of silicon oxide, titanium oxide, and aluminum oxide. However, example embodiments are not limited thereto. The second portion P2 of the insulating liner 148B may include a second oxide, and the second oxide may include at least one of silicon oxide, titanium oxide, and aluminum oxide. However, example embodiments are not limited thereto. The second portion P2 of the insulating liner 148B may have the same material composition as the first portion P1 of the insulating liner 148B and may be continuously connected to the first portion P1 of the insulating liner 148B.

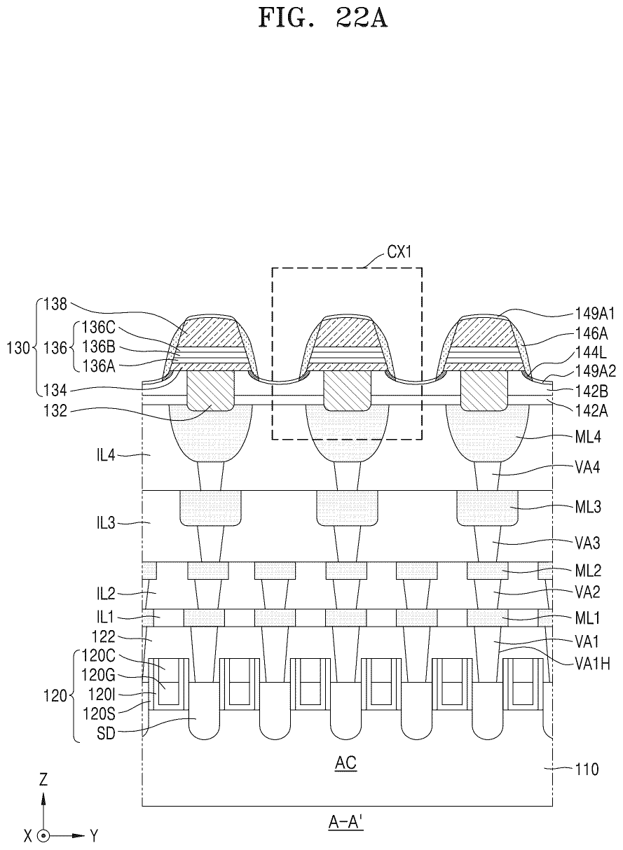

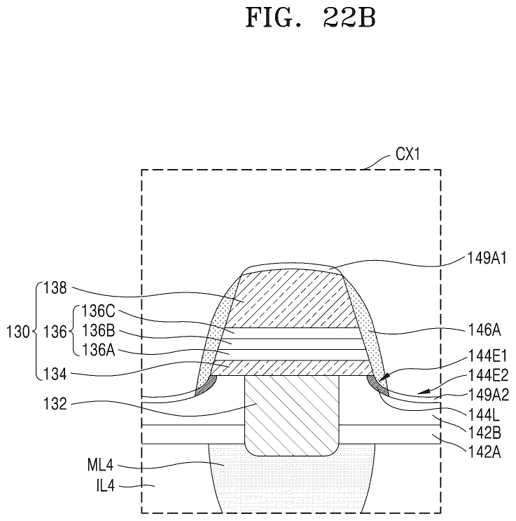

In some example embodiments, an ashing process may be performed at a relatively high temperature before performing an atomic layer deposition process to form the insulating liner 148B, and the entire thickness of an exposed portion (for example, a second portion 144E2 of the metal material redeposited layer 144L) of the metal material redeposited layer 144L (refer to FIGS. 22A and 22B) may be oxidized to form the second oxide layer 149A2 in the ashing process. The insulating liner 148B may then be formed by the atomic layer deposition process.

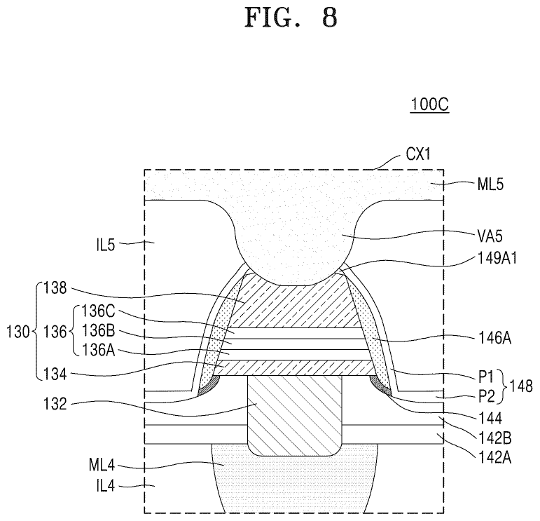

FIG. 8 is a cross-sectional view of a magnetoresistive memory device 100C according to some example embodiments.

Referring to FIG. 8, the magnetoresistive memory device 100C according to some example embodiments may be similar to the magnetoresistive memory device 100 described above with reference to FIGS. 1 to 4 except that the second capping spacer 146B is not formed. In some example embodiments, a sidewall of each of the plurality of magnetoresistive memory cells 130 may be surrounded by the first capping spacer 146A and the insulating liner 148, and the fifth insulating layer IL5 may be arranged on the sidewalls and upper surface of the insulating liner 148.

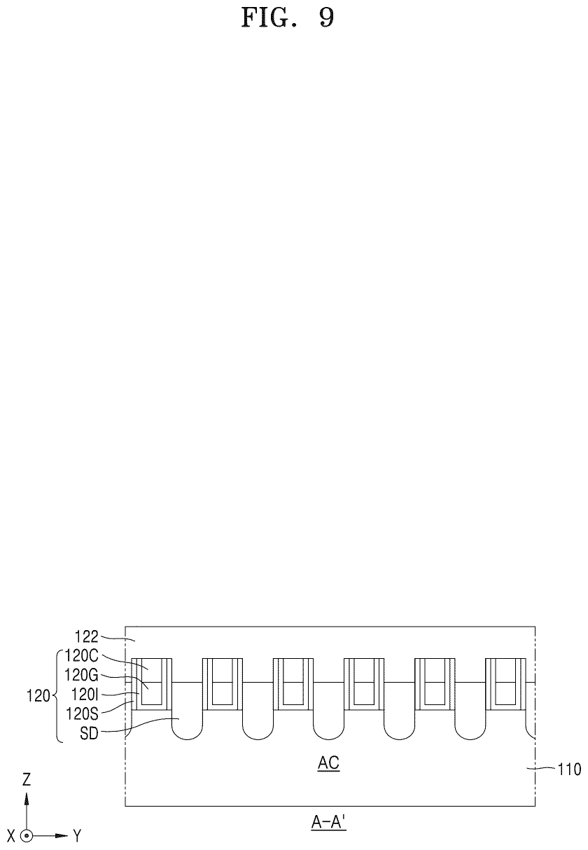

FIGS. 9, 10, 11, 12, 13, 14, 15A, 15A, 16A, 16B, 17A, 17B, 18, 19 are cross-sectional views illustrating a method of manufacturing the magnetoresistive memory device 100 according to some example embodiments. FIGS. 15B, 16B, and 17B are enlarged views of regions CX1 of FIGS. 15A, 16A, and 17A, respectively.

Referring to FIG. 9, the transistor 120 may be formed on the substrate 110. First, an active region AC in a pin shape may be formed on an upper side of the substrate 110, and the gate insulating layer 1201, the gate electrode 120G, and the gate capping layer 120C, which are sequentially arranged on an upper surface of the substrate 110, and the gate spacer 120S arranged on sidewalls of the gate insulating layer 1201, the gate electrode 120G, and the gate capping layer 120C may be formed on the substrate 110. In some example embodiments, a dummy gate electrode may be firstly formed, the gate spacer 120S may be formed on both sidewalls of the dummy gate electrode, the dummy gate electrode may be removed, and the gate insulating layer 1201, the gate electrode 120G, and the gate capping layer 120C may be sequentially formed in a space from which the dummy gate electrode was removed. Subsequently, the source/drain region SD may be formed by injecting impurities into the substrate 110 from both sides of the gate spacer 120S or by growing a semiconductor layer by using a selective epitaxy process.

Then, the first interlayer insulating film 122 covering the transistor 120 may be formed on the substrate 110.

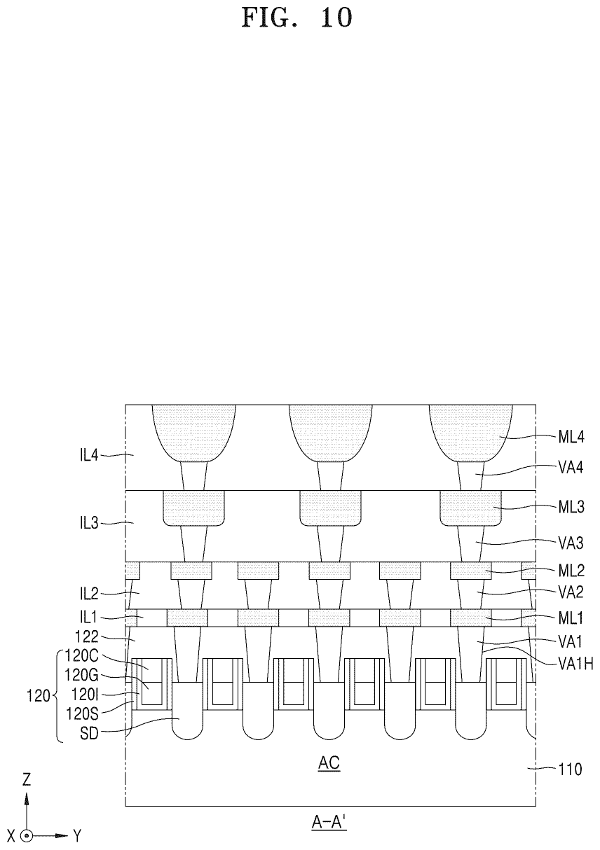

Referring to FIG. 10, the via hole VA1H exposing a portion of the transistor 120 (e.g., a portion of the source/drain region SD) may be formed by removing a portion of the first interlayer insulating film 122, and the first via VA1 may be formed within the via hole VA1H by using a conductive material.

Thereafter, the first wiring line layer ML1 and the first insulating layer IL1 may be formed on the first interlayer insulating film 122. In some example embodiments, a conductive layer for forming the first wiring line layer ML1 may be formed, and the first wiring line layer ML1 may be formed by patterning the conductive layer. Then, an insulating layer covering the first wiring line layer ML1 may be formed, and the first insulating layer IL1 may be formed by patterning an upper side of the insulating layer. In some other embodiments, the first insulating layer IL1 covering the first interlayer insulating film 122 and the first via VA1 may be firstly formed, an opening portion may be formed by removing a portion of the first insulating layer IL1, and the first wiring line layer ML1 may be formed by filling the opening portion with a conductive material.

Thereafter, the second to fourth insulating layers IL2, IL3, IL4, the second to fourth wiring line layers ML2, ML3, and ML4, and the second to fourth vias VA2, VA3, and VA4 may be formed on the first insulating layer IL1. In some example embodiments, the second insulating layer IL2 may be firstly formed, and the second via VA2 and the second wiring line layer ML2 may be formed by removing a portion of the second insulating layer IL2 and filling a portion from which the second insulating layer IL2 has been removed with a conductive material. Then, the third insulating layer IL3 may be formed, and the third via VA3 and the third wiring line layer ML3 may be formed by removing a portion of the third insulating layer IL3 and filling a portion from which the third insulating layer IL3 has been removed with a conductive material. Thereafter, the fourth insulating layer IL4 may be formed, and the fourth via VA4 and the fourth wiring line layer ML4 may be formed by removing a portion of the fourth insulating layer IL4 and filling a portion from which the fourth insulating layer IL4 has been removed with a conductive material.

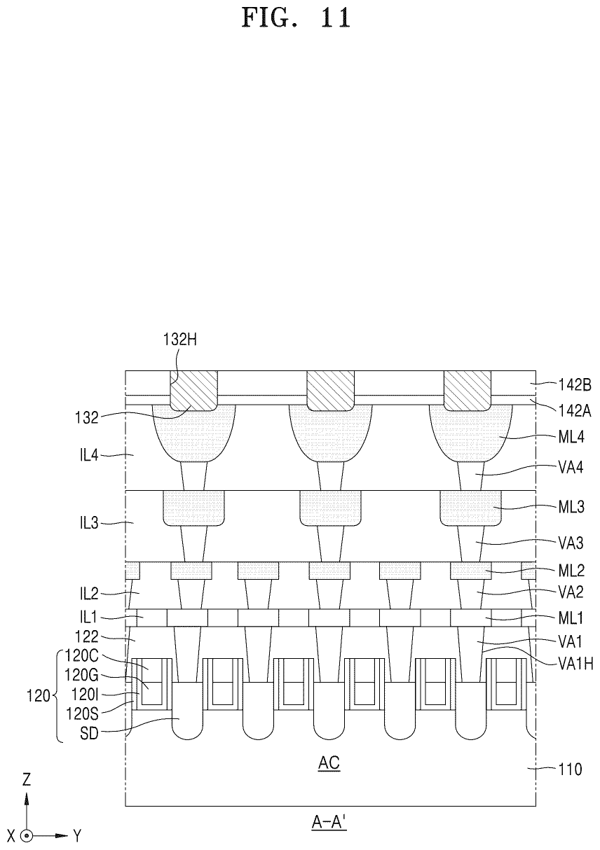

Referring to FIG. 11, the first isolation layer 142A and the second isolation layer 142B may be sequentially formed on the fourth wiring line layer ML4 and the fourth insulating layer IL4.

In some example embodiments, the first isolation layer 142A may include at least one of silicon oxide, silicon oxynitride, silicon carbon oxide, silicon nitride, and silicon carbon nitride. However, example embodiments are not limited thereto. The second isolation layer 142B may include at least one of silicon oxide, silicon oxynitride, silicon carbon oxide, silicon nitride, and silicon carbon nitride. However, example embodiments are not limited thereto.

A mask pattern may be formed on the second isolation layer 142B, and a portion of the second isolation layer 142B and a portion of the first isolation layer 142A may be removed by using the mask pattern as an etch mask to form a via contact hole 132H. Then, the via contact 132 may be formed by filling a conductive material within the via contact hole 132H.

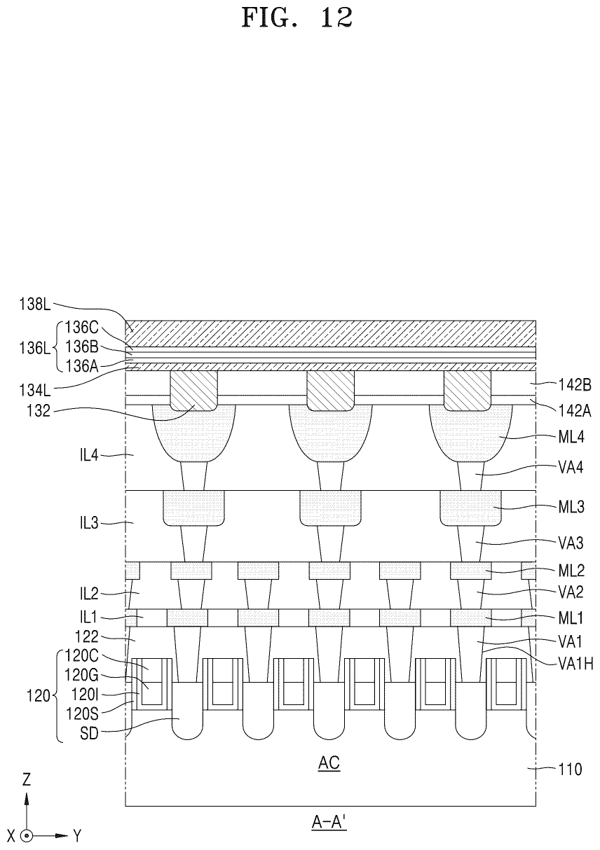

Referring to FIG. 12, a memory stack may be formed on the second isolation layer 142B and the via contact 132. In particular, a lower electrode layer 134L, a magnetic tunnel junction layer 136L, and an upper electrode layer 138L may be sequentially formed on the second isolation layer 142B and the via contact 132 to form the memory stack. The magnetic tunnel junction layer 136L may be formed by sequentially forming the fixed layer 136A, the tunnel barrier 136B, and the free layer 136C on the lower electrode layer 134L.

In some example embodiments, the lower electrode layer 134L, the magnetic tunnel junction layer 136L, and the upper electrode layer 138L may be formed by using at least one of a chemical vapor deposition process, an atomic layer deposition process, and a physical vapor deposition process. However, example embodiments are not limited thereto.

In some example embodiments, the lower electrode layer 134L may be formed by using W, Co, Ru, Mo, TiN, WN, CoN, MoN, or a combination thereof. The fixed layer 136A may be formed by using Fe, Co, Ni, or alloys thereof, and a multi-layered structure thereof. For example, the fixed layer 136A may include CoFeB, CoFe, NiFe, FePt, CoPt, or the like. The tunnel barrier 136B may be formed by using at least one selected from among oxides of Mg, Ti, Al, MgZn, and MgB, and nitrides of Ti and V. The free layer 136C may be formed by using Fe, Co, Ni, Pd, and Pt, or alloys thereof, and a multi-layered structure thereof. The upper electrode layer 138L may be formed by using W, Co, Ru, Mo, TiN, WN, CoN, MoN, or a combination thereof. However, the example embodiments above are not limited thereto.

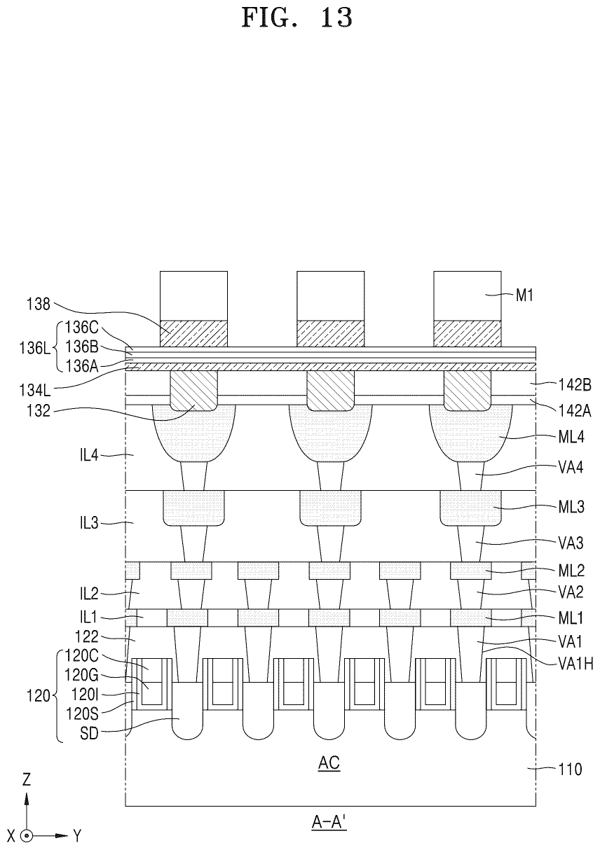

Referring to FIG. 13, a mask pattern M1 may be formed on the upper electrode layer 138L. The upper electrode 138 may be formed by removing a portion of the upper electrode layer 138L (refer to FIG. 12) by using the mask pattern M1 as an etch mask.

In some example embodiments, the mask pattern M1 may have a plurality of island-type pattern shapes spaced apart in the first horizontal direction X and the second horizontal direction Y. In some example embodiments, an etching process for forming the upper electrode 138 may be a dry etching process or a wet etching process. For example, the etching process for forming the upper electrode 138 may be performed within a first process chamber and may be performed under an etching condition having an etching selectivity for the upper electrode layer 138L (for example, using an etchant capable of removing the upper electrode layer 138L at a relatively high etching rate).

As the upper electrode 138 is formed by patterning the upper electrode layer 138L, a portion of an upper surface of the magnetic tunnel junction layer 136L, which is not covered by the upper electrode 138, may be exposed. For example, an upper surface of the free layer 136C, which is not covered by the upper electrode 138, may be exposed.

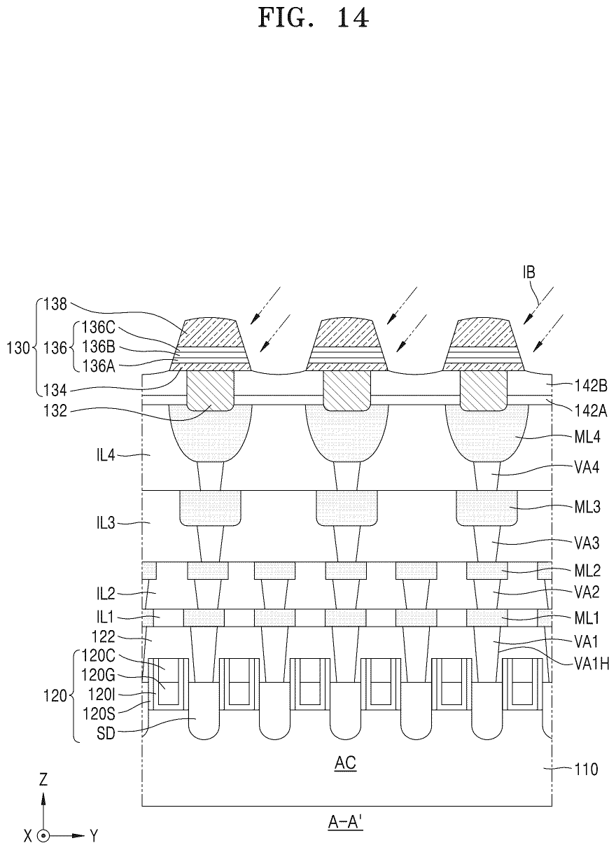

Referring to FIG. 14, the magnetic tunnel junction pattern 136 and the lower electrode 134 may be formed by etching portions of the magnetic tunnel junction layer 136L and the lower electrode layer 134L by using the upper electrode 138 as an etch mask.

In some example embodiments, a process of etching the magnetic tunnel junction layer 136L and the lower electrode layer 134L may be an ion beam etching process using an ion beam IB. In some example embodiments, the ion beam IB may include inert ions. In some example embodiments, the process of etching the magnetic tunnel junction layer 136L and the lower electrode layer 134L may be performed within a second process chamber, and portions of the magnetic tunnel junction layer 136L and the lower electrode layer 134L may be removed by directing the inert ions (e.g., argon ions) having relatively high energy onto the magnetic tunnel junction layer 136L and the lower electrode layer 134L. In some example embodiments, the ion beam IB may be directed to have a certain inclination angle from an upper surface of the substrate 110 in the etching process.

Referring to FIGS. 15A and 15B, as the upper electrode 138 is formed by patterning the upper electrode layer 138L after the magnetic tunnel junction pattern 136 and the lower electrode 134 are formed by an etching process, a portion of an upper surface of the second isolation layer 142B, which is not covered by the lower electrode 134, may be exposed. As a portion of an upper side of the second isolation layer 142B is removed together in the etching process, the second isolation layer 142B may have a recessed upper surface shape.

In some example embodiments, in the etching process, some of composition materials forming the magnetic tunnel junction layer 136L and the lower electrode layer 134L may be absorbed or redeposited onto the recessed upper surface of the second isolation layer 142B, thereby forming a continuous layer of materials or an at least partially connected layer of materials. The layer of materials may be referred to as the metal material redeposited layer 144L. In some example embodiments, the metal material redeposited layer 144L may include at least one of Fe, Co, Ni, Ru, Ti, Pd, Pt, and Mo. However, example embodiments are not limited thereto.

Here, the via contact 132, the lower electrode 134, the magnetic tunnel junction pattern 136, and the upper electrode 138 are referred to as the magnetoresistive memory cell 130. The plurality of magnetoresistive memory cells 130 may be spaced apart in the first horizontal direction X and the second horizontal direction Y and may be arranged at a higher vertical level than the fourth insulating layer IL4 and the fourth wiring line layer ML4. In some example embodiments, a portion of the magnetoresistive memory cell 130 may have an inclined sidewall, and for example, a sidewall of the lower electrode 134, a sidewall of the magnetic tunnel junction pattern 136, and a sidewall of the upper electrode 138 may be formed to be inclined at a certain angle and aligned with respect to each other. The metal material redeposited layer 144L may be arranged to be gently connected to the inclined sidewall of the lower electrode 134.

Thereafter, a first spacer layer 146AL covering the upper electrode 138, the magnetic tunnel junction pattern 136, and the lower electrode 134 may be formed. In some example embodiments, the first spacer layer 146AL may be formed by using silicon nitride or silicon oxynitride. In some example embodiments, a process of forming the first spacer layer 146AL may be an atomic layer deposition process or a chemical vapor deposition process. However, example embodiments are not limited thereto.

In some example embodiments, the process of forming the first spacer layer 146AL may be performed in situ with a formation process of the magnetic tunnel junction pattern 136 and the lower electrode 134 (e.g., an ion beam etching process), and for example, a formation process of the first spacer layer 146AL may follow after the formation process of the magnetic tunnel junction pattern 136 and the lower electrode 134 without breaking the vacuum. However, example embodiments are not limited thereto.

In some example embodiments, the first spacer layer 146AL may be conformally formed on the sidewalls of the upper electrode 138, the magnetic tunnel junction pattern 136, and the lower electrode 134, and the upper surface of the metal material redeposited layer 144L.

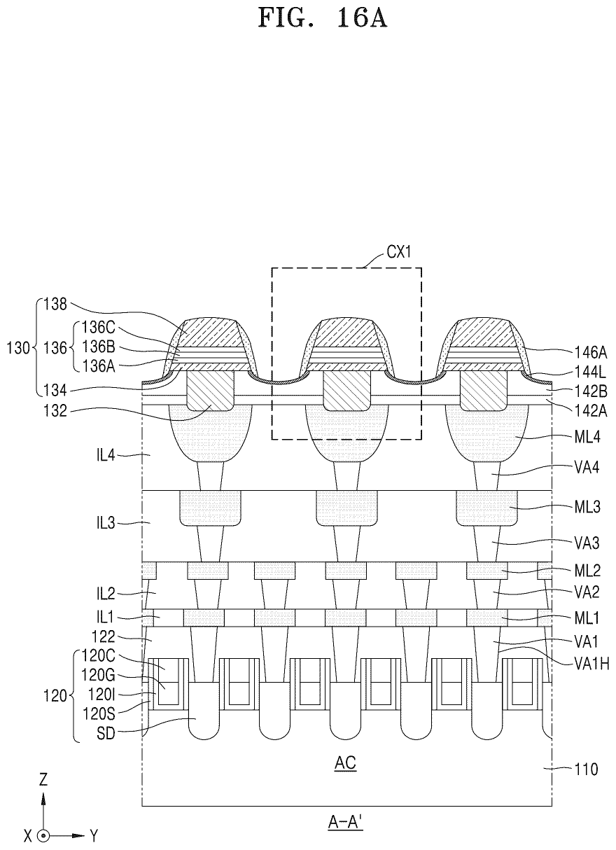

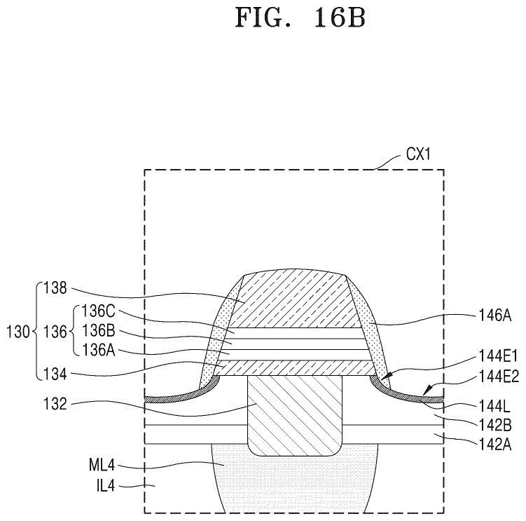

Referring to FIGS. 16A and 16B, an anisotropic etching process may be performed on the first spacer layer 146AL (refer to FIGS. 15A and 15B) to remove a portion of the first spacer layer 146AL on the upper surface of the upper electrode 138 and a portion of the first spacer layer 146AL on the upper surface of the second isolation layer 142B (or an upper surface of the metal material redeposited layer 144L). The first spacer layer 146AL may remain on the sidewalls of the upper electrode 138, the magnetic tunnel junction pattern 136, and the lower electrode 134 due to the anisotropic etching process, and the first spacer layer 146AL, which remains on the sidewalls of the upper electrode 138, the magnetic tunnel junction pattern 136, and the lower electrode 134, may be referred to as the first capping spacer 146A.

In some example embodiments, as a result of performing the anisotropic etching process, an end portion of the first capping spacer 146A (or a lowermost end of the first capping spacer 146A) may cover a first portion 144E1 of the metal material redeposited layer 144L. The first portion 144E1 of the metal material redeposited layer 144L may refer to a portion of the metal material redeposited layer 144L, which is arranged adjacent to the magnetoresistive memory cell 130, and may refer to, for example, a portion of the metal material redeposited layer 144L, which surrounds the magnetoresistive memory cell 130 and is covered by the first capping spacer 146A in a plan view. A portion of the metal material redeposited layer 144L, which is not covered by the first capping spacer 146A, may be referred to as a second portion 144E2.

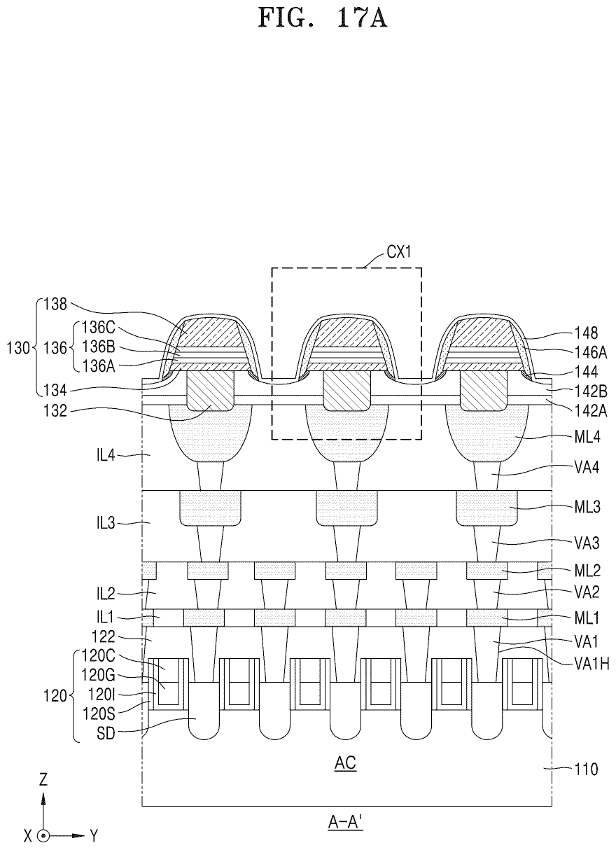

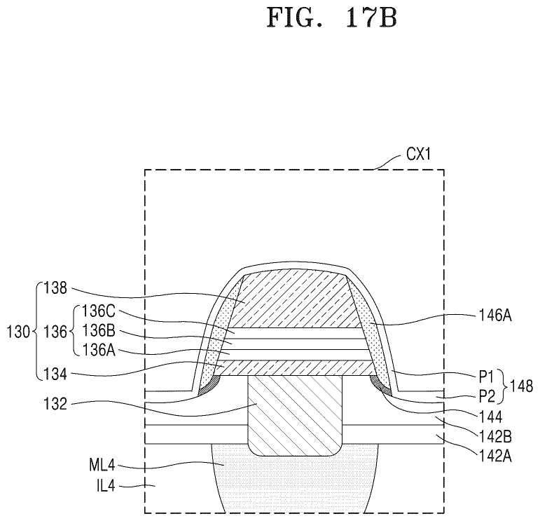

Referring to FIGS. 17A and 17B, the insulating liner 148 may be formed on the upper surfaces of the upper electrode 138, the first capping spacer 146A, and the metal material redeposited layer 144L.

In some example embodiments, the insulating liner 148 may be formed by an atomic layer deposition (ALD) process. In some example embodiments, the insulating liner 148 may be formed by a plasma enhanced atomic layer deposition (PEALD) process. In some example embodiments, the insulating liner 148 may be formed by using an ALD process using oxygen radicals. The insulating liner 148 may be formed by using a process condition for forming at least one of silicon oxide, titanium oxide, and aluminum oxide. However, example embodiments are not limited thereto. Hereinafter, a representative description is made with respect to a case in which the process condition for forming silicon oxide is used to form the insulating liner 148.

In some example embodiments, a formation process of the insulating liner 148 may be performed by repeating a deposition cycle multiple times, and each deposition cycle may include a precursor supply step, a first purge step, a reactant supply step, and a second purge step.

In some example embodiments, a precursor of a first material may be supplied in the precursor supply step. In some example embodiments, when the insulating liner 148 includes silicon oxide, a silicon precursor may be supplied in the precursor supply step. The silicon precursor may be a precursor including silicon and may include, for example, tridimethylaminosilane (TDMAS), hexachlorodisilane (HCDS), diisopropylaminosilane (DIPADS), 1,2-bis(diisopropylamino) disilane (BDIPADS), or the like. However, example embodiments are not limited thereto.

In some example embodiments, when the insulating liner 148 includes titanium oxide, a titanium precursor, such as titanium tetrachloride (TiCl₄), tetrakis (dimethylamido) titanium (TDMAT), or tetrakis (diethylamino) titanium (TDEAT) may be supplied in the precursor supply step. In some example embodiments, when the insulating liner 148 includes aluminum oxide, an aluminum precursor, such as trimethylaluminum (TMA) or triethylaluminum (TEA), may be supplied in the precursor supply step. However, example embodiments are not limited thereto.

In the precursor supply step, a precursor of the first material may be adsorbed on a surface of a deposition target, for example, exposed surfaces of the upper electrode 138, the magnetic tunnel junction pattern 136, the lower electrode 134, and the metal material redeposited layer 144L.

In some example embodiments, in the first purge step, an excess precursor of the first material, for example, an excess silicon precursor, may be removed or exhausted.

In some example embodiments, in the reactant supply step, oxygen gas and plasma may be supplied. In the reactant supply step, oxygen gas may be converted into oxygen radicals as plasma is applied, and the oxygen radicals may be supplied to the surface of the deposition target. In some example embodiments, the substrate 110 may be arranged within a plasma discharge region or at a relatively close distance from the plasma discharge region, oxygen radicals may be generated at a relatively close distance from the substrate 110, and a relatively large amount of oxygen radicals may be supplied to the surface of the deposition target. In addition, the oxygen radicals generated at a relatively close distance from the substrate 110 may have high reactivity, and a formation rate of the insulating liner 148 may be relatively high.

In some example embodiments, oxygen gas may be supplied during the reactant supply step and may also be constantly and continuously supplied throughout an entire deposition cycle.

In some example embodiments, in the reactant supply step, a monolayer of silicon oxide may be formed by a reaction of oxygen radicals with the silicon precursor adsorbed onto the surface of the deposition target. In some example embodiments, the monolayer of silicon oxide may be formed on the upper surface of the upper electrode 138 and the sidewall of the first capping spacer 146A.

In some example embodiments, in the second purge step, excess oxygen gas, oxygen radicals, or reaction by-products may be removed or exhausted.

In some example embodiments, the deposition cycle may be repeated so that the insulating liner 148 having a desired thickness is formed. In some example embodiments, the insulating liner 148 may be formed to have about 1 to about 10 nanometers. In some example embodiments, the insulating liner 148 may be formed to have about 1 to about 5 nanometers.

In some example embodiments, in the reactant supply step, a metal material included in the metal material redeposited layer 144L at the second portion 144E2 of the metal material redeposited layer 144L may be exposed to oxygen radicals or an oxidizing atmosphere. Accordingly, oxidation of the metal material included in the second portion 144E2 of the metal material redeposited layer 144L may occur, and at least a portion of the metal material may be converted into a metal oxide or a silicon metal oxide. In some example embodiments, when the deposition cycle is repeatedly performed to form the insulating liner 148, a thickness of the metal oxide or silicon metal oxide formed within the second portion 144E2 of the metal material redeposited layer 144L may gradually increase and be merged into the insulating liner 148.

Here, a portion of the insulating liner 148, which is formed from the second portion 144E2 of the metal material redeposited layer 144L, may be referred to as the second portion P2. A portion of the insulating liner 148, which is formed on the upper surface of the upper electrode 138 and the sidewall of the first capping spacer 146A, may be referred to as the first portion P1.

In some example embodiments, the first portion P1 of the insulating liner 148 may include a first oxide represented by a chemical formula of AOₓ, and A may include at least one of Si, Ti, and Al. In some example embodiments, the second portion P2 of the insulating liner 148 may include a second oxide represented by a chemical formula of AMₓO_{y}, A may include at least one of Si, Ti, and Al, and M may include at least one of Fe, Co, Ni, Ru, Ti, Pd, Pt, and Mo. However, example embodiments are not limited thereto.

In some example embodiments, the deposition cycle may be repeated so that the insulating liner 148 having a desired thickness is formed. For example, a number of deposition cycles may be repeatedly performed so that the entire thickness of the second portion 144E2 of the metal material redeposited layer 144L is converted into the second portion P2 of the insulating liner 148. For example, the entire thickness of the second portion 144E2 of the metal material redeposited layer 144L is converted into the second portion P2 of the insulating liner 148, and thus a portion of the metal material redeposited layer 144L may not remain between the second portion P2 of the insulating liner 148 and the second isolation layer 142B.

In some example embodiments, in the formation process of the insulating liner 148, the first portion 144E1 of the metal material redeposited layer 144L may not be exposed to oxygen radicals or an oxidizing atmosphere by being covered by the first capping spacer 146A. The first portion 144E1 of the metal material redeposited layer 144L may remain without being oxidized and may remain in an annular shape around one magnetoresistive memory cell 130 in a plan view. The first portion 144E1 of the metal material redeposited layer 144L may be referred to as the metal material residue layer 144.

In some example embodiments, the second portion P2 of the insulating liner 148 may be arranged between two adjacent magnetoresistive memory cells 130, and accordingly, the metal material residue layer 144 around one magnetoresistive memory cell 130 may not be electrically connected to the metal material residue layer 144 around another one magnetoresistive memory cell 130 adjacent to the one magnetoresistive memory cell 130. For example, the second portion P2 of the insulating liner 148 may be arranged between the metal material residue layer 144 around the one magnetoresistive memory cell 130 and the metal material residue layer 144 around the other one magnetoresistive memory cell 130 adjacent to the one magnetoresistive memory cell 130.

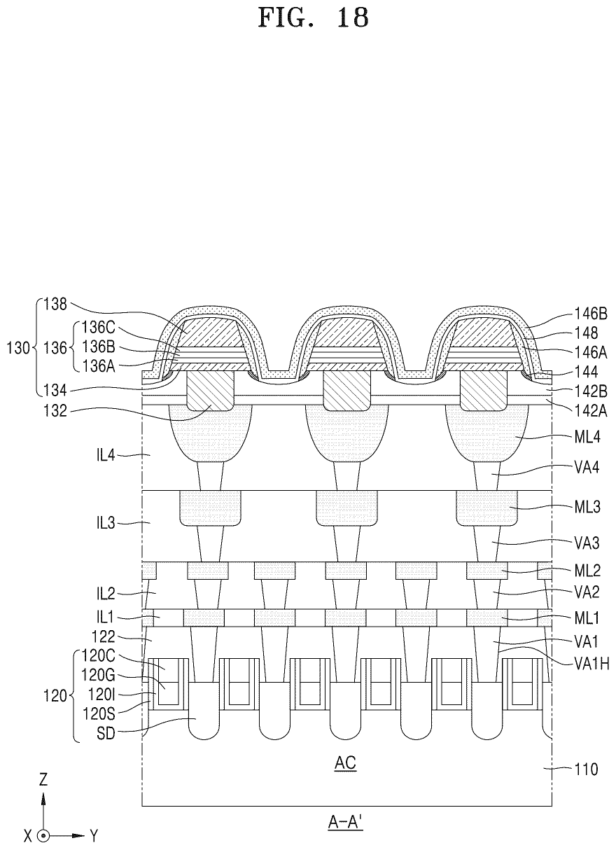

Referring to FIG. 18, the second capping spacer 146B may be formed on an upper surface of the insulating liner 148. The second capping spacer 146B may be conformally arranged on the first portion P1 and the second portion P2 of the insulating liner 148. In some example embodiments, the second capping spacer 146B may be formed by using silicon nitride or silicon oxynitride. In some example embodiments, a process of forming the second capping spacer 146B may be an ALD process or a chemical vapor deposition process. However, example embodiments are not limited thereto.

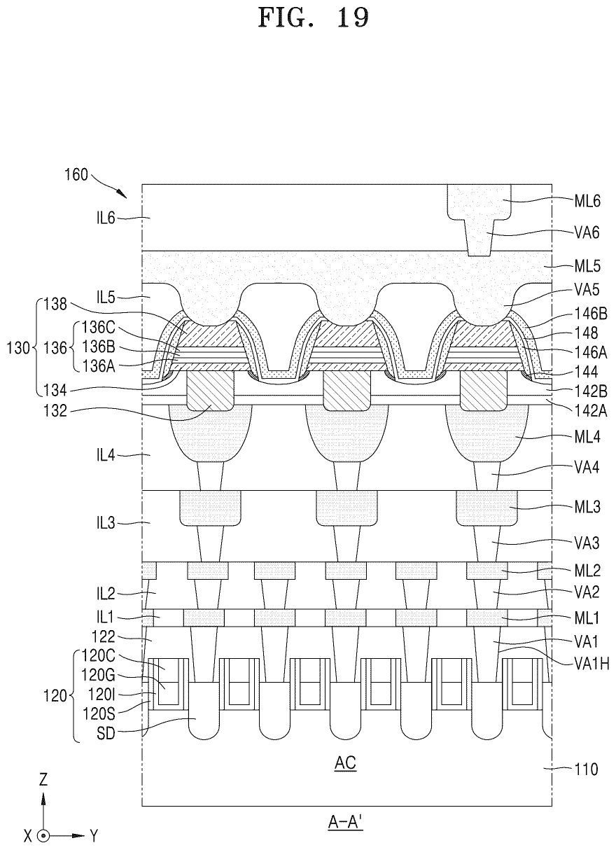

Referring to FIG. 19, the fifth insulating layer IL5 may be formed on the second capping spacer 146B. Thereafter, the fifth via VA5 and the fifth wiring line layer ML5 may be formed by removing a portion of the fifth insulating layer IL5 and filling a portion from which the fifth insulating layer IL5 has been removed with a conductive material. Then, the sixth insulating layer IL6 may be formed, and the sixth via VA6 and the sixth wiring line layer ML6 may be formed by removing a portion of the sixth insulating layer IL6 and filling a portion from which the sixth insulating layer IL6 has been removed with a conductive material.

The magnetoresistive memory device 100 may be completed by performing the above processes.

According to the method of manufacturing the magnetoresistive memory device 100 according to some example embodiments, the insulating liner 148 may be formed by using an ALD process instead of performing a recess process to remove a deposited layer of a metal material. In a process of forming the insulating liner 148, the metal material redeposited layer 144L may be oxidized and converted into a second oxide including metal, and the second portion P2 of the insulating liner 148 may be formed. Accordingly, even at fine pitches, leakage current between adjacent memory cells may be significantly reduced, and a recess process for removing the metal material redeposited layer 144L may be omitted, thereby limiting and/or preventing an undesired exposure or damage to an underlying line material. Therefore, the magnetoresistive memory device 100 may have improved device performance.

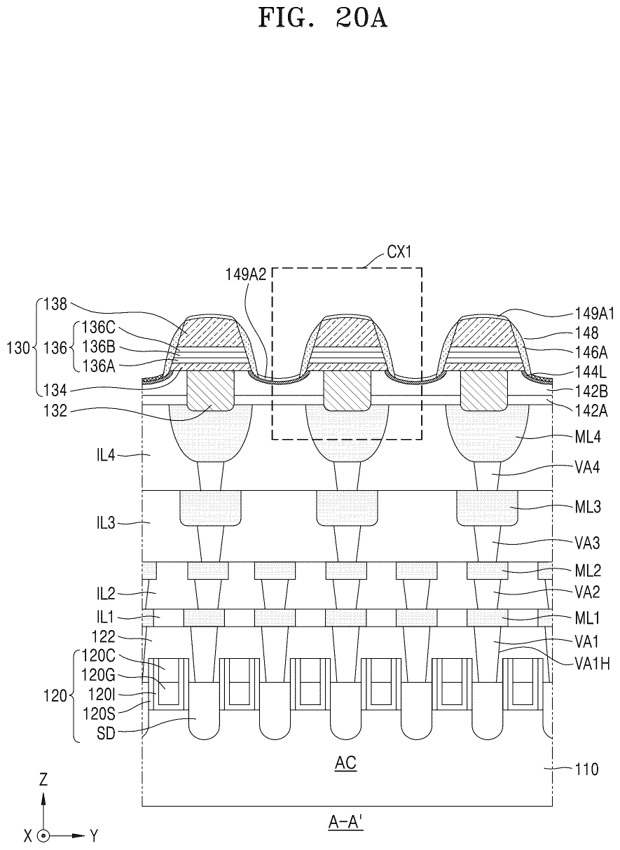

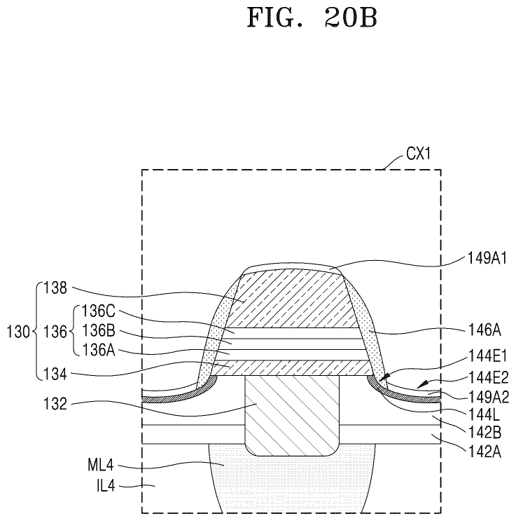

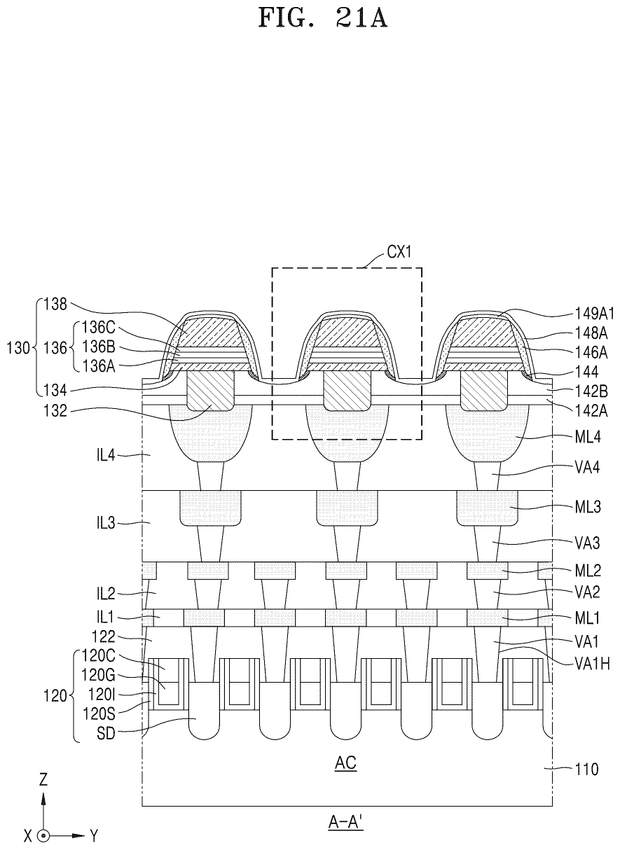

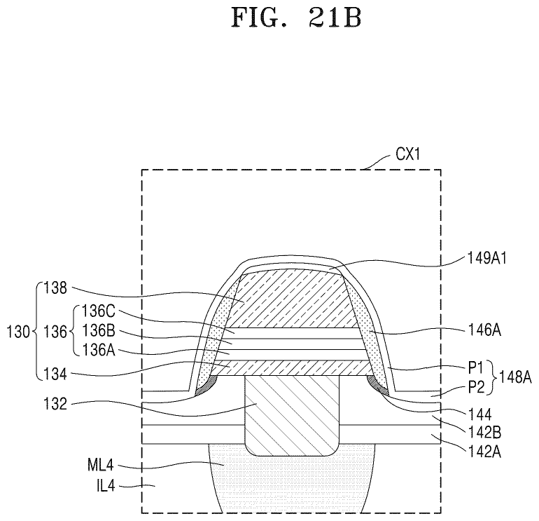

FIGS. 20A, 20B, 21A, and 21B are cross-sectional views illustrating a method of manufacturing the magnetoresistive memory device 100A according to some example embodiments. FIGS. 20B and 21B are enlarged views of regions CX1 of FIGS. 20A and 20B, respectively.

Referring to FIGS. 20A and 20B, in a state in which the first capping spacer 146A is formed, an ashing process may be performed before performing a process of forming the insulating liner 148A. In some example embodiments, the ashing process may be performed at a temperature of about 100° C. to about 500° C. In the ashing process, an oxygen source, such as oxygen, ozone, or the like, and/or plasma may be additionally supplied to form an oxidizing atmosphere.

In some example embodiments, in the ashing process, a metal material included in the upper electrode 138 may be exposed to an oxidizing atmosphere at a high temperature, and the metal material may be oxidized to form the first oxide layer 149A1 on the upper surface of the upper electrode 138. In some example embodiments, the first oxide layer 149A1 may include a metal oxide of a material included in the upper electrode 138. In some example embodiments, the first oxide layer 149A1 may include an oxide of at least one material from among W, Co, Ru, Mo, TiN, Wn, CoN, and MoN. However, example embodiments are not limited thereto. For example, when the upper electrode 138 includes titanium, the first oxide layer 149A1 may include titanium oxide. For example, when the upper electrode 138 includes titanium nitride, the first oxide layer 149A1 may include titanium oxynitride.

In some example embodiments, in the ashing process, the metal material included in metal material redeposited layer 144L at the second portion 144E2 of the metal material redeposited layer 144L may be exposed to an oxidizing atmosphere at a high temperature. The metal material may be oxidized, and thus a portion of the thickness of an upper side of the second portion 144E2 of the metal material redeposited layer 144L may be converted into a metal oxide. A portion converted into the metal oxide may be referred to as the second oxide layer 149A2.

Referring to FIGS. 21A and 21B, the insulating liner 148A may be formed on the first oxide layer 149A1, the second oxide layer 149A2, and the first capping spacer 146A. In some example embodiments, the process of forming the insulating liner 148A may have similar features as those described with reference to FIGS. 17A and 17B. For example, the insulating liner 148A may be formed through an ALD process using oxygen radicals.

In some example embodiments, the insulating liner 148A may include the first portion P1 and the second portion P2, and in some example embodiments, the first portion P1 of the insulating liner 148A may be arranged on the first oxide layer 149A1 and the first capping spacer 146A. In some example embodiments, the first oxide layer 149A1 may be arranged between the first portion P1 of the insulating liner 148A and the upper surface of the upper electrode 138.

In some example embodiments, the second portion P2 of the insulating liner 148A may be arranged on the second isolation layer 142B. During the ALD process using oxygen radicals, a metal material included in the metal material redeposited layer 144L at the second portion 144E2 of the metal material redeposited layer 144L may be exposed to the oxygen radicals or an oxidizing atmosphere. Accordingly, oxidation of the metal material included in the second portion 144E2 of the metal material redeposited layer 144L may occur, and at least a portion of the metal material may be converted into a metal oxide or a silicon metal oxide. When a deposition cycle is repeatedly performed to form the insulating liner 148A, a thickness of the metal oxide or silicon metal oxide formed within the second portion 144E2 of the metal material redeposited layer 144L may gradually increase and be merged into the insulating liner 148A. In addition, a portion of the second oxide layer 149A2 formed through the ashing process may also be merged into the insulating liner 148B.

In some example embodiments, the first portion P1 of the insulating liner 148A may include a first oxide represented by a chemical formula of AOₓ, and A may include at least one of Si, Ti, and Al. However, example embodiments are not limited thereto. In some example embodiments, the second portion P2 of the insulating liner 148A may include a second oxide represented by a chemical formula of AMₓO_{y}, A may include at least one of Si, Ti, and Al, and M may include at least one of Fe, Co, Ni, Ru, Ti, Pd, Pt, and Mo. However, example embodiments are not limited thereto.

Thereafter, the magnetoresistive memory device 100A may be completed by performing subsequent processes.

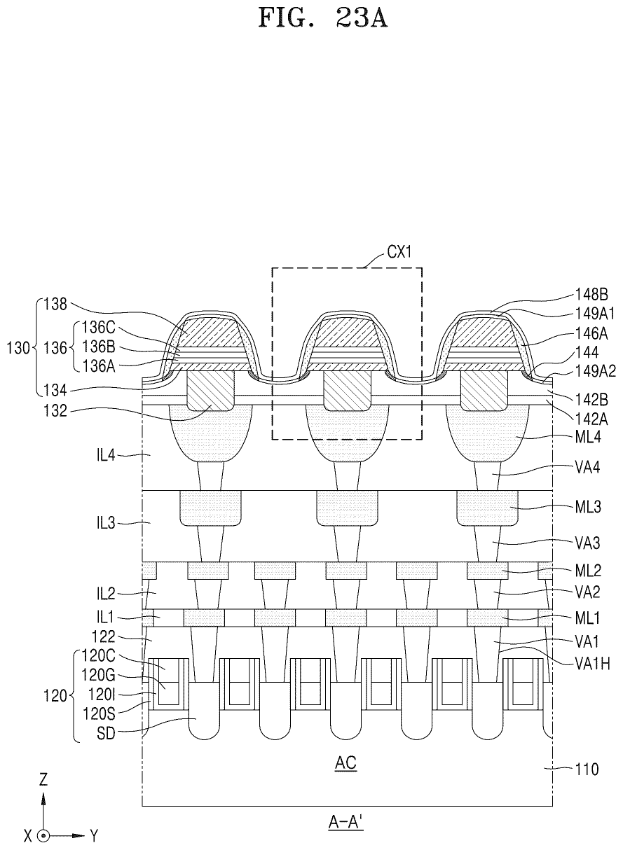

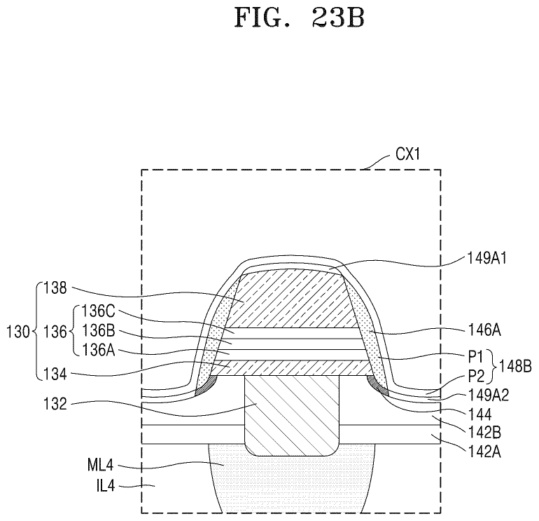

FIGS. 22A, 22B, 23A, and 23B are cross-sectional views illustrating a method of manufacturing the magnetoresistive memory device 100B according to some example embodiments. FIGS. 22B and 23B are enlarged views of regions CX1 of FIGS. 22A and 23A, respectively.

Referring to FIGS. 22A and 22B, in a state in which the first capping spacer 146A is formed, an ashing process may be performed before performing a process of forming the insulating liner 148B. In some example embodiments, the ashing process may be performed at a temperature of about 100° C. to about 500° C. In the ashing process, an oxygen source, such as oxygen, ozone, or the like, and/or plasma may be additionally supplied to form an oxidizing atmosphere.

In some example embodiments, in the ashing process, the metal material included in metal material redeposited layer 144L at the second portion 144E2 of the metal material redeposited layer 144L may be exposed to an oxidizing atmosphere at a high temperature. The metal material may be oxidized, and thus an entire thickness of the second portion 144E2 of the metal material redeposited layer 144L may be converted into a metal oxide. A portion converted into the metal oxide may be referred to as the second oxide layer 149A2.

In some example embodiments, the second oxide layer 149A2 may include a metal oxide represented by a chemical formula of MₓO_{y}, and M may include at least one of Fe, Co, Ni, Ru, Ti, Pd, Pt, and Mo. However, example embodiments are not limited thereto.

Referring to FIGS. 23A and 23B, the insulating liner 148B may be formed on the first oxide layer 149A1, the second oxide layer 149A2, and the first capping spacer 146A. In some example embodiments, the process of forming the insulating liner 148B may have similar features as those described with reference to FIGS. 17A and 17B. For example, the insulating liner 148B may be formed through an ALD process using oxygen radicals.

In some example embodiments, the insulating liner 148A may include the first portion P1 and the second portion P2, and each of the first portion P1 and the second portion P2 may include at least one of silicon oxide, titanium oxide, and aluminum oxide. However, example embodiments are not limited thereto.

Thereafter, the magnetoresistive memory device 100B may be completed by performing subsequent processes.

According to a method of manufacturing a magnetoresistive memory device according to the inventive concepts, a metal redeposited layer of an etching residue in a process of patterning a memory cell may be oxidized by using an oxidation process of an ALD method. Accordingly, even at fine pitches, leakage current between adjacent memory cells may be significantly reduced, and a recess process for removing the metal redeposited layer may be omitted, thereby limiting and/or preventing an undesired exposure or damage to an underlying line material. Therefore, the magnetoresistive memory device may have improved device performance.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the inventive concepts has been particularly shown and described with reference to example embodiments thereof, it will be understood that various changes in form and details may be made therein without departing from the spirit and scope of the following claims.

What is claimed is:

1. A method of manufacturing a magnetoresistive memory device, the method comprising:
forming an isolation layer and a via contact on a substrate, the via contact having a sidewall surrounded by the isolation layer;
forming a memory stack on the isolation layer and the via contact,
the memory stack comprising
a lower electrode layer,
a magnetic tunnel junction layer, and
an upper electrode layer;
forming a plurality of memory cells by patterning the memory stack using an ion beam etching process;
forming a metal material redeposited layer during the ion beam etching process on an upper surface of the isolation layer; and
forming an insulating liner on the plurality of memory cells by using an atomic layer deposition process,
wherein the insulating liner comprises
a first portion covering the plurality of memory cells, the first portion comprising a first oxide, and
a second portion formed by oxidation of at least a portion of the metal material redeposited layer, the second portion comprising a second oxide.

2. The method of claim 1, further comprising:
forming a first capping spacer on sidewalls of the plurality of memory cells after the forming of the plurality of memory cells,
wherein the forming of the insulating liner comprises forming the first portion of the insulating liner on the first capping spacer.

3. The method of claim 2, wherein
the metal material redeposited layer comprises
a first portion arranged adjacent to the sidewalls of the plurality of memory cells, and the first portion covered by the first capping spacer, and
a second portion arranged between two adjacent memory cells among the plurality of memory cells, and the second portion not covered by the first capping spacer.

4. The method of claim 3, wherein
the second portion of the metal material redeposited layer is oxidized and converted into the second portion of the insulating liner during the forming of the insulating liner, and
the first portion of the metal material redeposited layer remains without being oxidized.

5. The method of claim 4, wherein a bottom surface of the first portion of the metal material redeposited layer is continuously connected to a bottom surface of the second portion of the insulating liner.

6. The method of claim 1, wherein
the first oxide comprises at least one of silicon oxide, titanium oxide, or aluminum oxide,
the second oxide comprises at least one of silicon metal oxide, titanium metal oxide, or aluminum metal oxide, and
a metal comprised in the second oxide comprises at least one of Fe, Co, Ni, Ru, Ti, Pd, Pt, or Mo.

7. The method of claim 1, wherein the forming of the insulating liner is performed by the atomic layer deposition process using oxygen radicals.

8. The method of claim 7, wherein
the forming of the insulating liner is performed by repeating a deposition cycle multiple times, the deposition cycle comprising a precursor supply step, a first purge step, a reactant supply step, and a second purge step, and
a reactant gas comprising oxygen and plasma are supplied during the reactant supply step.

9. The method of claim 7, wherein a reactant gas comprising oxygen is continuously supplied throughout a deposition cycle.

10. The method of claim 1, further comprising:
forming a line structure on the substrate,
wherein the line structure comprises
a wiring line layer arranged on at least one vertical level,
an insulating layer surrounding the wiring line layer, and
the via contact is electrically connected to the wiring line layer.

11. The method of claim 1, further comprising:
forming an oxide layer by oxidizing a portion of an upper side of the metal material redeposited layer after the forming of the plurality of memory cells and before the forming of the insulating liner.

12. The method of claim 11, wherein
the forming of the oxide layer is performed using an ashing process, and
the ashing process is performed at a temperature of 100 degrees to 500 degrees.

13. A method of manufacturing a magnetoresistive memory device, the method comprising:
forming a wiring line structure on a substrate, the wiring line structure comprising a wiring line layer and an insulating layer;
forming an isolation layer on the wiring line structure;
forming a memory stack on the isolation layer,
the memory stack comprising
a lower electrode layer,
a magnetic tunnel junction layer, and
an upper electrode layer;
forming a plurality of memory cells by removing a portion of the memory stack using an ion beam etching process;
removing a portion of an upper side of the isolation layer during the ion beam etching process so that the isolation layer has a recessed upper surface, and a metal material redeposited layer is formed on the recessed upper surface of the isolation layer;
forming a first capping spacer on sidewalls of the plurality of memory cells; and
oxidizing a portion of the metal material redeposited layer that is not covered by the first capping spacer.

14. The method of claim 13, wherein
the metal material redeposited layer comprises
a first portion arranged adjacent to the sidewalls of the plurality of memory cells, the first portion covered by the first capping spacer,
a second portion arranged between two adjacent memory cells among the plurality of memory cells, the second portion not covered by the first capping spacer, and
the oxidizing of the portion of the metal material redeposited layer comprises oxidizing the second portion of the metal material redeposited layer.

15. The method of claim 14, wherein the oxidizing of the portion of the metal material redeposited layer is performed by an atomic layer deposition process using oxygen radicals.

16. The method of claim 14, wherein
an insulating liner is formed on the plurality of memory cells during the oxidizing of the portion of the metal material redeposited layer that is not covered by the first capping spacer, and
the insulating liner comprises
a first portion arranged on upper surfaces of the plurality of memory cells and a sidewall of the first capping spacer, and
a second portion formed by oxidation of the second portion of the metal material redeposited layer.

17. The method of claim 16, wherein
the first portion of the insulating liner comprises a first oxide,
the second portion of the insulating liner comprises a second oxide,
the first oxide comprises at least one of silicon oxide, titanium oxide, or aluminum oxide,
the second oxide comprises at least one of silicon metal oxide, titanium metal oxide, or aluminum metal oxide, and
a metal comprised in the second oxide comprises at least one of Fe, Co, Ni, Ru, Ti, Pd, Pt, or Mo.

18. The method of claim 16, wherein a bottom surface of the first portion of the metal material redeposited layer is continuously connected to a bottom surface of the second portion of the insulating liner at the recessed upper surface of the isolation layer.

19. A method of manufacturing a magnetoresistive memory device, the method comprising:
forming a wiring line structure on a substrate, the wiring line structure comprising a wiring line layer and an insulating layer;
forming an isolation layer on the wiring line structure;
forming a memory stack on the isolation layer,
the memory stack comprising
a lower electrode layer,
a magnetic tunnel junction layer, and
an upper electrode layer;
forming a plurality of memory cells by removing a portion of the memory stack by using an ion beam etching process;
removing a portion of an upper side of the isolation layer during the ion beam etching process so that the isolation layer has a recessed upper surface, and a metal material redeposited layer is formed on the recessed upper surface of the isolation layer;
forming a first capping spacer on sidewalls of the plurality of memory cells, such that a first portion of the metal material redeposited layer is covered by the first capping spacer, and a second portion of the metal material redeposited layer is not covered by the first capping spacer; and
forming an insulating liner by an atomic layer deposition process using oxygen radicals, wherein
a first portion of the insulating liner covers the plurality of memory cells and the first capping spacer, and
a second portion of the insulating liner is formed by oxidizing the second portion of the metal material redeposited layer.

20. The method of claim 19, wherein
the first portion of the metal material redeposited layer after the forming of the insulating liner remains without being oxidized, and
a bottom surface of the first portion of the metal material redeposited layer is continuously connected to a bottom surface of the second portion of the insulating liner at the recessed upper surface of the isolation layer.
